(19) United States
(12) Patent Application Publication
(10) Pub. No.: US 2021/0222298 A1
(43) Pub. Date: Jul. 22, 2021

(54) PLASMA CVD DEVICE AND PLASMA CVD METHOD

(71) Applicant: ULVAC, INC., Chigasaki-shi (JP)

(72) Inventors: Tadamasa KOBAYASHI, Chigasaki-shi (JP); Hideaki ZAMA, Chigasaki-shi (JP)

(21) Appl. No.: 16/977,275

(22) PCT Filed: Feb. 13, 2020
(86) PCT No.: PCT/JP2020/005552

§ 371 Date: Sep. 1, 2020

(30) Foreign Application Priority Data
Feb. 25, 2019 (JP) 2019-031620

(51) Int. Cl. C23C 16/455; C23C 16/40; C23C 16/509; H01L 21/02

(52) U.S. Cl. CPC C23C 16/45561; C23C 16/402; C23C 16/509; H01L 29/7869; H01L 21/02211; H01L 21/02274; H01L 21/02164

(57) ABSTRACT

A plasma CVD device (10) includes a vacuum container (21) including a space accommodating a film formation subject (S), a storage (30) storing hydrogen-free isocyanate silane and heating the isocyanate silane to generate an isocyanate silane gas supplied to the vacuum container (21), a pipe (11) connecting the storage (30) to the vacuum container (21) to supply the isocyanate silane gas generated by the storage (30) to the vacuum container (21), a temperature adjuster (12) adjusting a temperature of the pipe (11) to 83° C. or higher and 180° C. or lower, an electrode (22) disposed in the vacuum container (21), and a power supply (23) supplying high-frequency power to the electrode (22). When a silicon oxide film is formed on the film formation subject (S) in the vacuum container (21), pressure of the vacuum container (21) is greater than or equal to 50 Pa and less than 500 Pa.

### TECHNICAL FIELD

The present invention relates to a plasma CVD device and a plasma CVD method.

### BACKGROUND ART

In a known structure of a thin film transistor that includes a semiconductor layer including an oxide semiconductor as a main component, a gate insulation layer covers a gate electrode, a semiconductor layer is formed on the gate insulation layer, and an insulation layer is formed on the semiconductor layer. When a source electrode and a drain electrode are formed from a metal layer formed on the insulation layer and a portion of the semiconductor layer that is not covered by the insulation layer, the insulation layer is used as an etching stopper layer. Such an insulation layer is formed of, for example, a silicon oxide film (refer to, for example, Patent Document 1).

### PRIOR ART DOCUMENT

### Patent Document

Patent Document 1: International Patent Publication No. WO2012/169397

### SUMMARY OF THE INVENTION

### Problems that the Invention is to Solve

A silicon oxide film may be formed using a plasma CVD method. When forming a silicon oxide film, one of silane (SiH₄) and tetraethoxysilane (TEOS) is often used as the material of the silicon oxide film. Since these materials contain hydrogen, the silicon oxide film formed on the semiconductor layer contains hydrogen. Hydrogen in the silicon oxide film disperses toward the semiconductor layer in the boundary surface between the silicon oxide film and the semiconductor layer and reduces the semiconductor layer. As a result, oxygen deficiency occurs in the semiconductor layer. Such oxygen deficiency in a semiconductor layer causes unstable properties of a thin film transistor including the semiconductor layer. Therefore, there is a need for a film formation method that reduces hydrogen content of a silicon oxide film.

Such an issue is not limited to a silicon oxide film used as an insulation layer formed on a semiconductor layer and is applied to a situation in which dispersion of hydrogen to a layer in contact with a silicon oxide film needs to be limited.

It is an object of the present invention to provide a plasma CVD device and a plasma CVD method that lower the concentration of hydrogen atoms in a silicon oxide film.

### Means for Solving the Problem

One embodiment of a plasma CVD device includes a vacuum container including a space configured to accommodate a film formation subject, a storage configured to store isocyanate silane that does not contain hydrogen and heat the isocyanate silane in the storage to generate an isocyanate silane gas that is supplied to the vacuum container, a pipe that connects the storage to the vacuum container to supply the isocyanate silane gas generated by the storage to the vacuum container, a temperature adjuster configured to adjust a temperature of the pipe to 83° C. or higher and 180° C. or lower, an electrode disposed in the vacuum container; and a power supply configured to supply high-frequency power to the electrode. When a silicon oxide film is formed on the film formation subject in the vacuum container, pressure of the vacuum container is greater than or equal to 50 Pa and less than 500 Pa.

One embodiment of a plasma CVD method includes setting a temperature of a pipe to 83° C. or higher and 180° C. or lower. The pipe is connected to a storage and a vacuum container configured to accommodate a film formation subject to supply an isocyanate silane gas to the vacuum container. The isocyanate silane gas is generated by the storage and does not contain hydrogen. The method further includes setting pressure of the vacuum container to 50 Pa or greater and less than 500 Pa.

With each configuration described above, an isocyanate silane gas that does not contain hydrogen is used to form a silicon oxide film. Thus, the concentration of hydrogen atoms in the silicon oxide film is lowered as compared to when a hydrogen-containing gas such as silane or a tetraethoxysilane is used to form a silicon oxide film.

The plasma CVD device described above may further includes an oxygen-containing gas supply portion configured to supply an oxygen-containing gas to the vacuum container. The oxygen-containing gas may be oxygen gas. The isocyanate silane may be tetraisocyanate silane. The storage is configured to supply a tetraisocyanate silane gas to the pipe at a first flow rate. The oxygen-containing gas supply portion is configured to supply the oxygen gas at a second flow rate. In this case, a ratio of the second flow rate to the first flow rate may be greater than or equal to 1 and less than or equal to 100. The configuration described above forms a silicon oxide film having a concentration of hydrogen atoms that is less than or equal to 1×10²¹ atoms/cm³.

In the plasma CVD device described above, the ratio of the second flow rate to the first flow rate may be greater than or equal to 2 and less than or equal to 100. The pressure of the vacuum container may be greater than or equal to 50 Pa and less than or equal to 350 Pa. The configuration described above increases the reliability of the concentration of hydrogen atoms in the silicon oxide film being less than or equal to 1×10²¹ atoms/cm³.

In the plasma CVD device described above, the pipe is a first pipe. The plasma CVD device may further include an oxygen-containing gas supply portion configured to supply oxygen-containing gas to the vacuum container and a second pipe connected to the oxygen-containing gas supply portion and also connected an intermediate portion of the first pipe extending toward the vacuum container to supply the oxygen-containing gas to the first pipe.

In the configuration described above, the isocyanate silane gas and the oxygen-containing gas are mixed in the first pipe, and the mixed gas is supplied to the vacuum container. This limits variations in the oxygen concentration in the vacuum container. As a result, variations in the properties of the silicon oxide film formed in the vacuum container are limited.

### BRIEF DESCRIPTION OF THE DRAWINGS

FIG. 1 is a schematic block diagram illustrating the structure of one embodiment of a plasma CVD device.

FIG. 2 is a cross-sectional view illustrating the structure of a thin film transistor including a silicon oxide film formed using the plasma CVD device.

FIG. 3 is a graph illustrating the relationship between a hydrogen concentration of a silicon oxide film and a pressure of a vacuum container at each ratio of the flow rate of oxygen gas to the flow rate of tetraisocyanate silane gas.

FIG. 4 is a table illustrating the relationship of the flow rate of oxygen gas, the pressure of the vacuum container, and the pressure of tetraisocyanate silane gas in a first pipe.

FIG. 5 is a vapor pressure curve of tetraisocyanate silane.

FIG. 6 is a graph illustrating the relationship between a carrier concentration of a semiconductor layer and the hydrogen concentration of a silicon oxide film.

FIG. 7 is a graph illustrating drain current of a thin film transistor in a first test.

FIG. 8 is a graph illustrating drain current of a thin film transistor in a second test.

### EMBODIMENTS OF THE INVENTION

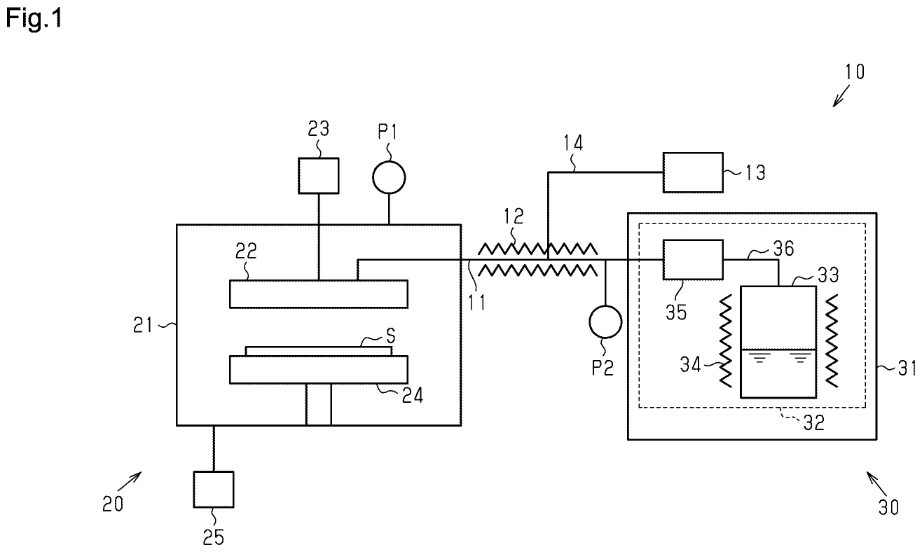

One example of a plasma CVD device and a plasma CVD method will now be described with reference to FIGS. 1 to 8. The structure of the plasma CVD device, the plasma CVD method, and tests will be described below in sequence.

Plasma CVD Device Structure

The structure of the plasma CVD device will be described with reference to FIG. 1. FIG. 1 schematically illustrates an example of the plasma CVD device.

As illustrated in FIG. 1, a plasma CVD device 10 includes a vacuum container 21, a storage 30, a first pipe 11, and a temperature adjuster 12. The vacuum container 21 includes a space that accommodates a film formation subject S. The storage 30 stores isocyanate silane that does not contain hydrogen. In the present embodiment, isocyanate silane is tetraisocyanate silane (Si(NCO)₄). The storage 30 heats Si(NCO)₄ in the storage 30 to generate a Si(NCO)₄ gas that is supplied to the vacuum container 21. The first pipe 11 is a pipe that connects the storage 30 to the vacuum container 21 to supply Si(NCO)₄ gas generated by the storage 30 to the vacuum container 21. The temperature adjuster 12 adjusts the temperature of the first pipe 11 to 83° C. or higher and 180° C. or lower. When a silicon oxide film is formed on the film formation subject S in the vacuum container 21, the pressure of the vacuum container 21 is greater than or equal to 50 Pa and less than 500 Pa.

The plasma CVD device 10 is configured to form a silicon oxide film using Si(NCO)₄ gas that does not contain hydrogen. Thus, the concentration of hydrogen atoms in the silicon oxide film is lower than that when a hydrogen-containing gas such as silane or a tetraethoxysilane is used to form a silicon oxide film.

The plasma CVD device 10 further includes an oxygen-containing gas supply portion 13 and a second pipe 14. The oxygen-containing gas supply portion 13 supplies oxygen-containing gas to the vacuum container 21. In the present embodiment, oxygen-containing gas is oxygen (O₂). The second pipe 14 is connected to the oxygen-containing gas supply portion 13 and is also connected to an intermediate portion of the first pipe 11 extending toward the vacuum container 21. The second pipe 14 is a pipe configured to supply O₂ gas to the first pipe 11.

Si(NCO)₄ gas and O₂ gas are mixed in the first pipe 11, and the mixed gas is supplied to the vacuum container 21. This limits variations in the oxygen concentration in the vacuum container 21. As a result, variations in the properties of a silicon oxide film formed in the vacuum container 21 are limited.

The plasma CVD device 10 further includes an electrode 22 and a power supply 23. The electrode 22 is disposed in the vacuum container 21. In the present embodiment, the electrode 22 is connected to the first pipe 11. The electrode 22 is also used as a dispersion portion that disperses the mixed gas of Si(NCO)₄ gas and oxygen gas supplied by the first pipe 11. The electrode 22 is, for example, a metal shower plate. The first pipe 11 is connected to the vacuum container 21 by the electrode 22.

The power supply 23 supplies high-frequency power to the electrode 22. The power supply 23 supplies, for example, high-frequency power having a frequency of 13 MHz or high-frequency power having a frequency of 27 MHz to the electrode 22.

A vacuum chamber 20 includes the vacuum container 21, the electrode 22, and the power supply 23, which are described above. The vacuum chamber 20 further includes a support 24 and a gas discharge portion 25. The support 24 is disposed in the vacuum container 21 and supports the film formation subject S. The support 24 is, for example, a stage that supports the film formation subject S. The support 24 may include a temperature adjuster disposed in the support 24 to adjust the temperature of the film formation subject S. In the plasma CVD device 10, the support 24 is also used as an opposing electrode opposed to the electrode 22. The plasma CVD device 10 is a parallel-plate-type plasma CVD device.

The gas discharge portion 25 is connected to the vacuum container 21. The gas discharge portion 25 reduces the pressure of the vacuum container 21 to a predetermined pressure. The vacuum container 21 includes, for example, various pumps and various valves.

The storage 30 includes a retaining container 31, an isothermal container 32, a tank 33, a tank temperature adjuster 34, a Si(NCO)₄ gas supply portion 35, and a Si(NCO)₄ gas pipe 36. The isothermal container 32 is disposed in the retaining container 31. The isothermal container 32 is configured to maintain the space defined by the isothermal container 32 at a predetermined temperature. The tank 33, the tank temperature adjuster 34, the Si(NCO)₄ gas supply portion 35, and the Si(NCO)₄ gas pipe 36 are disposed in the isothermal container 32. The tank temperature adjuster 34 is disposed outside the tank 33 to heat the tank 33 and Si(NCO)₄ stored in the tank 33. The tank 33 is configured to store Si(NCO)₄ that is in vapor-liquid equilibrium. The tank 33 is connected to the Si(NCO)₄ gas supply portion 35 by the Si(NCO)₄ gas pipe 6. The Si(NCO)₄ gas supply portion 35 is, for example, a mass flow controller. The Si(NCO)₄ gas supply portion 35 is connected to the first pipe 11. The Si(NCO)₄ gas supply portion 35 supplies Si(NCO)₄ gas, which is supplied from the tank 33 through the Si(NCO)₄ gas pipe 36, to the first pipe 11 at a predetermined flow rate.

The temperature adjuster 12 is disposed outside the first pipe 11 and heats the first pipe 11. The temperature adjuster 12 is configured to heat the first pipe 11 so that the temperature of the first pipe 11 and the temperature of a fluid flowing through the first pipe 11 are set to a substantially same temperature.

The oxygen-containing gas supply portion 13 is, for example, a mass flow controller. The oxygen-containing gas supply portion 13 supplies O₂ gas to the second pipe 14 at a predetermined flow rate. The second pipe 14 is connected to the first pipe 11. Preferably, the second pipe 14 is connected to the first pipe 11 at a position closer to the storage 30 than at least part of the heated portion of the first pipe 11. This allows Si(NCO)₄ gas and oxygen gas to be supplied to the vacuum container 21 while limiting decreases in the temperature of Si(NCO)₄ gas flowing through the first pipe 11 caused by O₂ gas.

A first pressure meter P1 may be attached to the vacuum container 21. The first pressure meter P1 is configured to measure the pressure of the vacuum container 21. A second pressure meter P2 may be attached to an intermediate portion of the first pipe 11 on a position downstream of the storage 30 and upstream of the temperature adjuster 12 in a direction in which Si(NCO)₄ gas flows through the first pipe 11. The second pressure meter P2 is configured to measure the pressure of the first pipe 11.

Plasma CVD Method

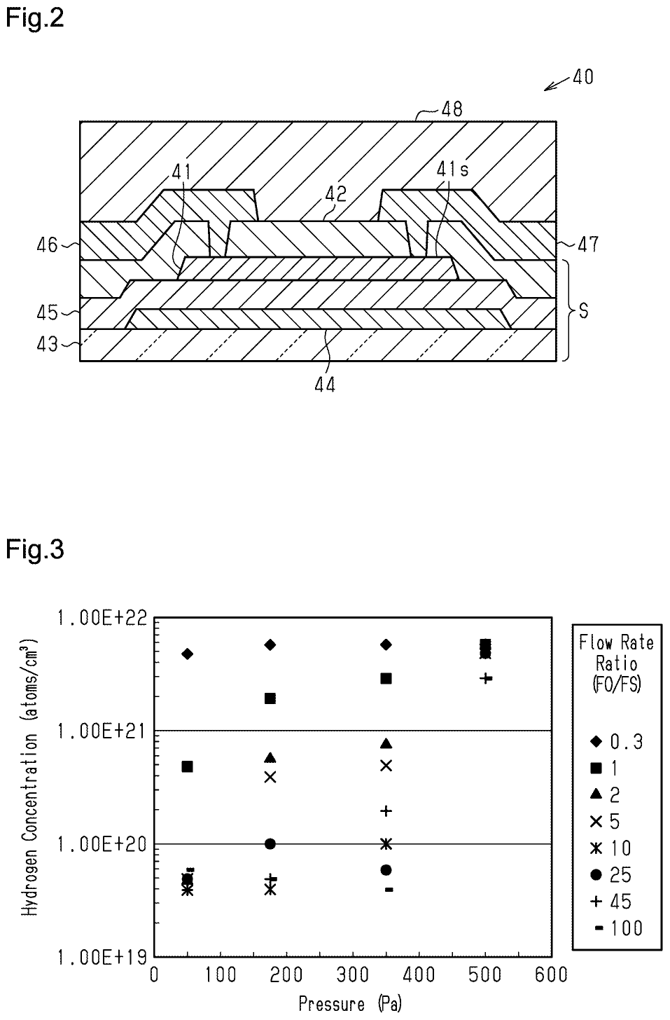

The plasma CVD method will now be described with reference to FIGS. 2 to 5.

The plasma CVD method includes setting the temperature of a pipe to 83° C. or higher and 180° C. or lower and setting the pressure of a vacuum container to 50 Pa or greater and less than 500 Pa. The pipe is connected to storage and a vacuum container that accommodates a film formation subject. The pipe supplies Si(NCO)₄ gas generated by the storage to the vacuum container. The plasma CVD method will be more specifically described below with reference to the drawings. Before description of the plasma CVD method, the structure of a thin film transistor including an insulation layer formed of a silicon oxide film using the plasma CVD method will be described.

The structure of the thin film transistor will be described with reference to FIG. 2. The thin film transistor includes a silicon oxide film formed using the plasma CVD device 10 as an insulation layer that is formed on a semiconductor layer.

As illustrated in FIG. 2, a thin film transistor 40 includes a semiconductor layer 41 and an insulation layer 42. The semiconductor layer 41 includes a surface 41s. The semiconductor layer 41 includes an oxide semiconductor as a main component. The oxide semiconductor is 90 mass percent or greater in the semiconductor layer 41.

The insulation layer 42 is located on the surface 41s of the semiconductor layer 41. In the insulation layer 42, silicon oxide is a main component, and a concentration of hydrogen atoms is less than or equal to 1×10²¹ atoms/cm³. The insulation layer 42 is a silicon oxide film formed using the plasma CVD device 10. The insulation layer 42 covers the surface 41s of the semiconductor layer 41 and a portion of a gate insulation layer 45 that is not covered by the semiconductor layer 41.

In the present embodiment, the semiconductor layer 41 is formed of a single layer. However, the semiconductor layer 41 may include at least one layer. More specifically, the semiconductor layer 41 may include multiple layers, that is, two or more layers. Preferably, each layer has a main component that is any one selected from a group consisting of InGaZnO, GaZnO, InZnO, InTiZnO, InAlZnO, ZnTiO, ZnO, ZnAlO, and ZnCuO.

The thin film transistor 40 includes the film formation subject S. The film formation subject S includes a substrate 43, a gate electrode 44, the gate insulation layer 45, and the semiconductor layer 41. The gate electrode 44 is located on a portion of the surface of the substrate 43. The gate insulation layer 45 covers the entire gate electrode 44 and the surface of the substrate 43 that is not covered by the gate electrode 44. The substrate 43 may be, for example, any one of a resin substrate formed from various resins, or a glass substrate. For example, molybdenum may be used as the material forming the gate electrode 44. For example, a silicon oxide layer or a lamination of a silicon oxide layer and a silicon nitride layer may be used as the gate insulation layer 45.

The semiconductor layer 41 is located on the surface of the gate insulation layer 45 at a position overlapping the gate electrode 44 in a direction in which the layers of the thin film transistor 40 are stacked. The thin film transistor 40 further includes a source electrode 46 and a drain electrode 47. The source electrode 46 and the drain electrode 47 are spaced apart from each other by a predetermined gap in an arrangement direction extending along a horizontal cross section of the thin film transistor 40. The source electrode 46 covers a portion of the insulation layer 42. The drain electrode 47 covers another portion of the insulation layer 42. Each of the source electrode 46 and the drain electrode 47 is electrically connected to the semiconductor layer 41 by contact holes formed in the insulation layer 42. The material forming the source electrode 46 and the material forming the drain electrode 47 may be, for example, molybdenum or aluminum.

The thin film transistor 40 further includes a protective film 48. The protective film 48 covers the source electrode 46, the drain electrode 47, and the portion of the insulation layer 42 exposed from the source electrode 46 and the drain electrode 47. The material forming the protective film 48 may be, for example, a silicone oxide.

As described above, in the thin film transistor 40, the insulation layer 42, which is a silicon oxide film, needs to have a concentration of hydrogen atoms that is less than or equal to 1×10²¹ atoms/cm³ to stabilize the properties of the thin film transistor 40. Hereafter, the concentration of hydrogen atoms is also referred to as the hydrogen concentration. The hydrogen concentration of the silicon oxide film is dependent on the pressure of the vacuum container 21 when the silicon oxide film is formed and the ratio (FO/FS) of a flow rate FO of O₂ gas to a flow rate FS of Si(NCO)₄ gas. Hereafter, the ratio of the flow rate FO to the flow rate FS is also referred to as the flow rate ratio.

FIG. 3 is a graph illustrating the relationship between the hydrogen concentration of the silicon oxide film and the pressure of the vacuum container 21 at each flow rate ratio. The relationship of the hydrogen concentration and the pressure of the vacuum container 21 illustrated in FIG. 3 is obtained when the conditions of forming the silicon oxide film are set as follows.

| | | |
|---|---|---|
| Si(NCO)₄ Gas Flow Rate | 55 | sccm |
| High-Frequency Power | 4000 | W |
| Electrode Area | 2700 | cm² |

As illustrated in FIG. 3, when the pressure of the vacuum container 21 is 50 Pa, a silicon oxide film having a hydrogen concentration of 1×10²¹ atoms/cm³ or less is formed. Also, when the pressure of the vacuum container 21 is 175 Pa or 350 Pa, a silicon oxide film having a hydrogen concentration of 1×10²¹ atoms/cm³ or less is formed. To form a silicon oxide film having the hydrogen concentration of 1×10²¹ atoms/cm³ or less, the value of the flow rate ratio tends to be increased as the pressure of the vacuum container 21 increases. When the pressure of the vacuum container 21 is 500 Pa, formation of a silicon oxide film having the hydrogen concentration of 1×10²¹ atoms/cm³ or less is hindered even when the flow rate ratio is 100. Taking into consideration practical flow rates of gases supplied by the oxygen-containing gas supply portion 13 and the Si(NCO)₄ gas supply portion 35, it is impracticable to set the flow rate ratio to be greater than 100. Thus, the pressure of the vacuum container 21 needs to be greater than or equal to 50 Pa and less than 500 Pa to form a silicon oxide film having the hydrogen concentration of 1×10²¹ atoms/cm³ or less.

In addition, setting of the flow rate ratio to be greater than or equal to 1 and less than or equal to 100 facilitates formation of a silicon oxide film having a hydrogen concentration of 1×10²¹ atoms/cm³ or less. Therefore, it is preferred that the flow rate ratio is set to be greater than or equal to 1 and less than or equal to 100. It is further preferred that the flow rate ratio is greater than or equal to 2 and less than or equal to 100 and the pressure of the vacuum container 21 is greater than or equal to 50 Pa and less than or equal to 350 Pa to form a silicon oxide film. This increases the reliability of the hydrogen concentration of the silicon oxide film being less than or equal to 1×10²¹ atoms/cm³.

When the pressure of the vacuum container 21 is greater than or equal to 50 Pa and less than 500 Pa and the flow rate ratio is greater than or equal to 1 and less than or equal to 100, a film formation rate of the silicon oxide film is also a practical value, that is, approximately greater than or equal to 100 nm/min and less than or equal to 200 nm/min.

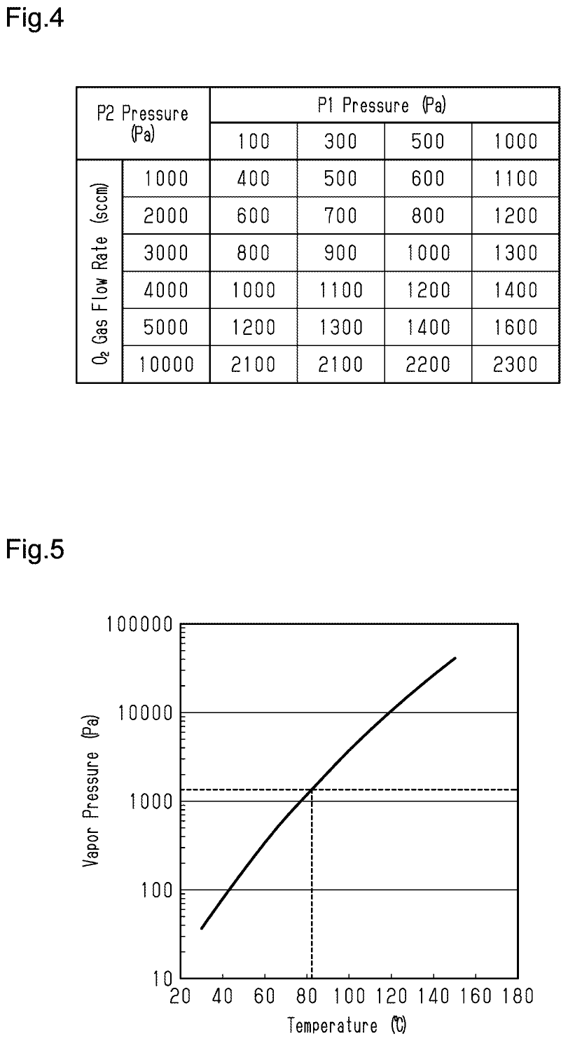

FIG. 4 is a table illustrating pressures measured by the second pressure meter P2 when the flow rate of O₂ gas supplied to the first pipe 11 is set to each value and the pressure of the vacuum container 21, that is, the pressure of the first pressure meter P1, is set to each value. As described above, to form a silicon oxide film having the hydrogen concentration of 1×10²¹ atoms/cm³ or less, the pressure of the vacuum container 21 needs to be less than 500 Pa. Since the flow rate ratio is 100 at the maximum, when the flow rate of Si(NCO)₄ gas is set to 55 sccm, the flow rate of O₂ gas is 5500 sccm at the maximum. Therefore, when the pressure of the first pipe 11 is 1500 Pa at the minimum, that is, the vapor pressure of the Si(NCO)₄ gas is 1500 Pa, Si(NCO)₄ gas that is in a vaporized state is supplied to the vacuum container 21 regardless of the flow rate of O₂ gas and the flow rate of the vacuum container 21.

FIG. 5 is a saturation vapor pressure curve of Si(NCO)₄ gas.

As illustrated in FIG. 5, when the temperature of Si(NCO)₄ gas is 83° C., the saturation vapor pressure of Si(NCO)₄ gas reaches 1500 Pa. Therefore, the temperature of Si(NCO)₄ gas, that is, the temperature of the first pipe 11 to which Si(NCO)₄ gas is supplied, needs to be greater than or equal to 83° C. The boiling point of Si(NCO)₄ is 186° C. When the upper limit value of the temperature of the first pipe 11 is set to 180° C., which is a value proximate to the boiling point of Si(NCO)₄ gas, Si(NCO)₄ gas is reliably supplied to the vacuum container 21.

[Tests]

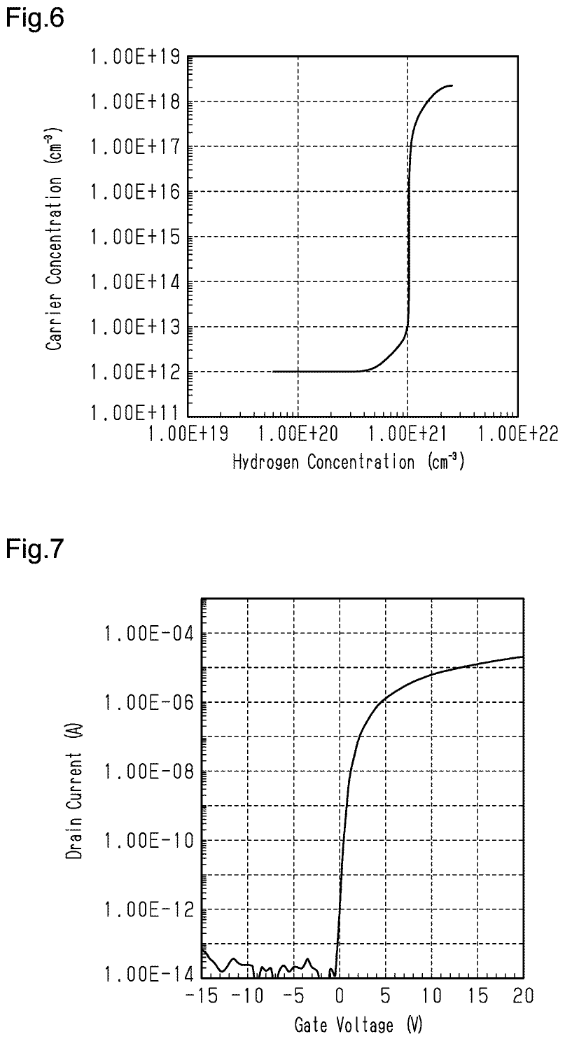

Tests will now be described with reference to FIGS. 6 to 8.

[Film Formation Condition]

The semiconductor layer and the insulation layer, which are layers of the thin film transistor described with reference to FIG. 2, are formed under the following conditions.

[Semiconductor Layer]

| Target | InGaZnO | |
|---|---|---|
| Sputter Gas | Argon (Ar) gas/Oxygen (O₂) gas | |
| Sputter Gas Flow Rate | 80 sccm(Ar)/6 sccm(O₂) | |
| Pressure of Film Formation Space | 0.3 | Pa |
| Power applied to Target | 240 | W |

| | |
|---|---|
| Target Area | 81 cm² (4-inch diameter) |

[Insulation Layer]

| Si(NCO)₄ Gas Flow Rate | 55 | sccm |
|---|---|---|
| Oxygen Gas Flow Rate | 16.5 sccm or greater and 5500 sccm or less | |
| Vacuum Container Pressure | 50 Pa or greater and 500 Pa or less | |
| High-Frequency Power | 4000 W or less | |
| Electrode Area | 2700 | cm² |

[Evaluation]

[Hydrogen Atom Concentration]

The concentration of hydrogen atoms in the insulation layer of each thin film transistor was measured using a secondary ion mass spectrometer (ADEPT1010, manufactured by ULVAC-PHI, Inc.). The concentration of hydrogen atoms in each insulation layer was as illustrated in FIG. 3.

[Carrier Concentration]

A carrier concentration of the semiconductor layer of each lamination was measured. The carrier concentration was measured using a Hall effect measurement device (HL55001U, manufactured by Nanometrics Inc.).

As illustrated in FIG. 6, when a concentration of hydrogen atoms in the insulation layer was greater than 1×10²¹ atoms/cm³, the carrier concentration of the semiconductor layer 41 was greater than 1×10¹⁶ atoms/cm³. When a concentration of hydrogen atoms in the insulation layer was less than or equal to 1×10²¹ atoms/cm³, the carrier concentration of the semiconductor layer was less than 1×10¹³ atoms/cm³.

More specifically, it was found that when a concentration of hydrogen atoms in the insulation layer was less than or equal to 1×10²¹ atoms/cm³, the carrier concentration of the semiconductor layer was significantly decreased as compared to when a concentration of hydrogen atoms in the insulation layer was greater than 1×10²¹ atoms/cm³. It is assumed that these results were obtained because the concentration of hydrogen atoms in the insulation layer that was less than or equal to 1×10²¹ atoms/cm³ significantly limited oxygen deficiency that would result from reduction of a semiconductor layer located below the insulation layer.

[First Test]

In a first test, a thin film transistor having the structure described above with reference to FIG. 2 was formed. The thin film transistor includes a gate electrode, a gate insulation layer, a semiconductor layer, an insulation layer, a source electrode, a drain electrode, and a protective film. In the thin film transistor of the first test, film formation conditions of the semiconductor layer were those described above, and film formation conditions of the insulation layer were as follows. The concentration of hydrogen atoms in the insulation layer was measured using the method described above and was found to be 5×10¹⁹ atoms/cm³.

| | | |
|---|---|---|
| Si(NCO)₄ Gas Flow Rate | 55 | sccm |
| Oxygen Gas Flow Rate | 2500 | sccm |
| Vacuum Container Pressure | 175 | Pa |
| High-Frequency Power | 4000 | W |
| Electrode Area | 2700 | cm² |

In the thin film transistor of the first test, the material forming the gate electrode, the source electrode, and the drain electrode was molybdenum. The material forming the gate insulation layer was a silicon oxide. The material forming the protection film was a silicon oxide.

[Second Test]

A thin film transistor in a second test was formed in the same process as the first test except that the film formation conditions of the insulation layer were as follows. The concentration of hydrogen atoms in the insulation layer was measured using the method described above and was found to be 2×10²¹ atoms/cm³.

| Film Formation Gas | Silane (SiH₄) | |
|---|---|---|
| Film Formation Gas Flow Rate | 70 | sccm |
| N₂O Gas Flow Rate | 3500 | sccm |
| Pressure of Film Formation Space | 200 | Pa |
| High-Frequency Power | 800 | W |
| Electrode Area | 2700 | cm² |

[Evaluation]

A semiconductor parameter analyzer (4155C, manufactured by Agilent Technologies, Inc.) was used to measure the transistor property, or voltage (Vg)-current (Id) property, of the thin film transistor of the first test and the thin film transistor of the second test. The measurement conditions of the transistor property were set as follows.

| | |
|---|---|
| Source Voltage | 0 V |
| Drain Voltage | 5 V |
| Gate Voltage | From −15 V to 20 V |
| Glass Substrate Temperature | Room Temperature |

As illustrated in FIG. 7, in the thin film transistor of the first test, the threshold voltage was 5.3 V, the activation voltage was 0.66 V, the electron mobility was 10.2 cm²/Vs, and the subthreshold swing value was 0.31 V/decade. The activation voltage is the gate voltage when the drain current is 10⁻⁹ A/cm². Thus, in the thin film transistor of the first test, that is, a thin film transistor including an insulation layer having a concentration of hydrogen atoms of 1×10²¹ atoms/cm³ or less, it was found that the thin film transistor operated normally. In other words, the transistor property was stable.

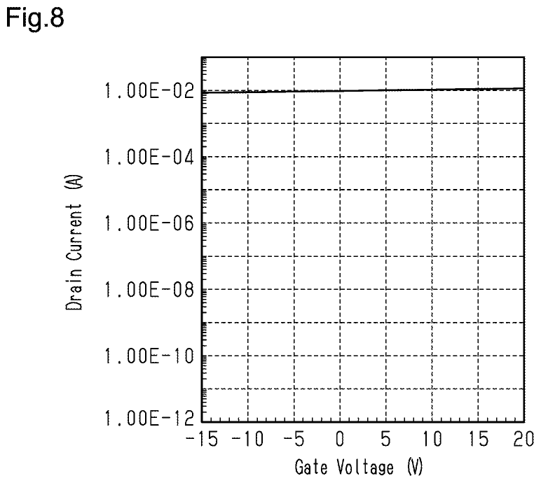

On the other hand, as illustrated in FIG. 8, the thin film transistor of the second test, that is, a thin film transistor including an insulation layer having a concentration of hydrogen atoms that is greater than 1×10²¹ atoms/cm³ did not operate normally. In other words, the transistor property was unstable.

As described above, the plasma CVD device and the plasma CVD method of the embodiment have the following advantages.

(1) Si(NCO)₄ gas that does not contain hydrogen is used to from a silicon oxide film. Thus, the concentration of hydrogen atoms in the silicon oxide film is lower than that when a hydrogen-containing gas such as silane or a tetraethoxysilane is used to form a silicon oxide film.

(2) The flow rate ratio is greater than or equal to 1 and less than or equal to 100. This allows for formation of a silicon oxide film having a concentration of hydrogen atoms that is less than or equal to 1×10²¹ atoms/cm³.

(3) The flow rate ratio is greater than or equal to 2 and less than or equal to 100 and the pressure of the vacuum container 21 is greater than or equal to 50 Pa and less than or equal to 350 Pa. This increases the reliability of the concentration of hydrogen atoms in the silicon oxide film being less than or equal to 1×10²¹ atoms/cm³.

(4) Si(NCO)₄ gas and O₂ gas are mixed in the first pipe 11, and the mixed gas is supplied to the vacuum container 21. This limits variations in the oxygen concentration in the vacuum container 21. As a result, variations in the properties of a silicon oxide film formed in the vacuum container 21 are limited.

The embodiment may be modified as follows.

[Second Pipe]

The second pipe 14 may be directly connected to the vacuum container 21 instead of being connected to the intermediate portion of the first pipe 11. In this case, the second pipe 14 may be connected to, for example, the electrode 22, which is used as the dispersion portion that disperses gas, or a supply hole formed in the vacuum container 21.

[Electrode]

The electrode 22 does not have to be used as the dispersion portion. In this case, for example, the plasma CVD device 10 may include a dispersion portion that is different from the electrode and disposed in the vacuum container 21. Alternatively, when the plasma CVD device 10 does not include a dispersion portion, the first pipe 11 may be connected to the supply hole formed in the vacuum container 21.

[Isocyanate Silane]

Isocyanate silane gas includes an isocyanate group and does not contain hydrogen. Isocyanate silane gas may be any one selected from, for example, Si(NCO)₃Cl gas, Si(NCO)₂Cl₂ gas, and Si(NCO)Cl₃ gas instead of tetraisocyanate silane gas described above.

[Oxygen-Containing Gas]

Oxygen-containing gas may be any one selected from, for example, ozone (O₃) gas, nitrous oxide (N₂O) gas, carbon monoxide (CO) gas, and carbon dioxide (CO₂) gas instead of oxygen gas described above.

[Silicon Oxide Film]

The silicon oxide film is not limited to an insulation layer of a thin film transistor and may be, for example, an insulation layer of a Si semiconductor device, a ferroelectric device, a power semiconductor device, a compound semiconductor device, or a surface acoustic wave (SAW) device.

### DESCRIPTION OF THE REFERENCE NUMERALS

10) plasma CVD device, 11) first pipe, 12) temperature adjuster, 13) oxygen-containing gas supply portion, 14) second pipe, 20) vacuum chamber, 21) vacuum container, 22) electrode, 23) power supply, 24) support, 25) gas discharge portion, 30) storage, 31) retaining container, 32) isothermal container, 33) tank, 34) tank temperature adjuster, 35) Si(NCO)₄ gas supply portion, 36) Si(NCO)₄ gas pipe, 40) thin film transistor, 41) semiconductor layer, 41s) surface, 42) insulation layer, 43) substrate, 44) gate electrode, 45) gate insulation layer, 46) source electrode, 47) drain electrode, 48) protective film, P1) first pressure meter, P2) second pressure meter, S) film formation subject.

1. A plasma CVD device, comprising:
a vacuum container including a space configured to accommodate a film formation subject;
a storage configured to store isocyanate silane that does not contain hydrogen and heat the isocyanate silane in the storage to generate an isocyanate silane gas that is supplied to the vacuum container;
a pipe that connects the storage to the vacuum container to supply the isocyanate silane gas generated by the storage to the vacuum container;
a temperature adjuster configured to adjust a temperature of the pipe to 83° C. or higher and 180° C. or lower;
an electrode disposed in the vacuum container; and
a power supply configured to supply high-frequency power to the electrode,
wherein when a silicon oxide film is formed on the film formation subject in the vacuum container, pressure of the vacuum container is greater than or equal to 50 Pa and less than 500 Pa.

2. The plasma CVD device according to claim 1, further comprising an oxygen-containing gas supply portion configured to supply an oxygen-containing gas to the vacuum container, wherein
the oxygen-containing gas is oxygen gas,
the isocyanate silane is tetraisocyanate silane,
the storage is configured to supply a tetraisocyanate silane gas to the pipe at a first flow rate,
the oxygen-containing gas supply portion is configured to supply the oxygen gas at a second flow rate,
a ratio of the second flow rate to the first flow rate is greater than or equal to 1 and less than or equal to 100.

3. The plasma CVD device according to claim 2, wherein
the ratio of the second flow rate to the first flow rate is greater than or equal to 2 and less than or equal to 100, and
the pressure of the vacuum container is greater than or equal to 50 Pa and less than or equal to 350 Pa.

4. The plasma CVD device according to claim 1, wherein
the pipe is a first pipe,
the plasma CVD device further comprises:
an oxygen-containing gas supply portion configured to supply oxygen-containing gas to the vacuum container; and
a second pipe connected to the oxygen-containing gas supply portion, and
the second pipe is also connected to an intermediate portion of the first pipe extending toward the vacuum container to supply the oxygen-containing gas to the first pipe.

5. A plasma CVD method, comprising:
setting a temperature of a pipe to 83° C. or higher and 180° C. or lower, wherein the pipe is connected to a storage and a vacuum container configured to accommodate a film formation subject to supply an isocyanate silane gas to the vacuum container, and the isocyanate silane gas is generated by the storage and does not contain hydrogen; and
setting pressure of the vacuum container to 50 Pa or greater and less than 500 Pa.
